(19) United States
(12) Patent Application Publication
(10) Pub. No.: US 2016/0186979 A1
(43) Pub. Date: Jun. 30, 2016

(54) EFFICIENT COOLING OF LASERS, LED AND PHOTONICS DEVICES

(71) Applicants: Mehmet Arik, Niskayuna, NY (US); Stanton Earl Weaver, JR., Northville, NY (US)

(72) Inventors: Mehmet Arik, Niskayuna, NY (US); Stanton Earl Weaver, JR., Northville, NY (US)

(73) Assignee: GE Lighting Solutions, LLC, Cleveland, OH (US)

(21) Appl. No.: 15/062,823

(22) Filed: Mar. 7, 2016

Related U.S. Application Data
(62) Division of application No. 11/824,058, filed on Jun. 29, 2007.

(51) Int. Cl. F21V 29/58; H01L 33/48; H01L 33/50; H01L 33/62; F21V 29/74; H01L 33/64

(52) U.S. Cl. CPC F21V 29/59; F21V 29/58; F21V 29/74; H01L 33/648; H01L 33/644; H01L 33/507; H01L 33/62; H01L 33/486; F21Y 2101/02; F21Y 2101/025; H01L 2933/0075

(57) ABSTRACT

The present invention provides an optoelectronic device comprising a heat source and a heat transfer fluid. The present invention also provides a method of preparing an optoelectronic device, which comprises (i) providing a heat source, and (ii) filling a space in the vicinity of the heat source with a heat transfer liquid. The optoelectronic device has gained technical merits such as improved heat removing efficiency, lower chip/junction temperature, increased lumen output, longer operational lifetime, and better reliability, among others.

This application is a divisional application of U.S. Ser. No. 11/824,058, filed Jun. 29, 2007, the disclosure of which is herein incorporated by reference.

### BACKGROUND OF THE INVENTION

The present invention is related to an optoelectronic device and method thereof. More particularly, the present invention provides an optoelectronic device comprising a heat generating electronics source and a heat transfer fluid.

Thermal management issues are becoming increasingly important to electronics and semiconductor manufacturers. For example, light emitting diodes (LEDs) have been available since the early 1960's in various forms, and are now widely applied in a variety of signs and message boards. The exponential growth of the efficacy of LEDs (in lumens per Watt) is the primary reason for their popularity. Tremendous power savings are possible when LED signals are used to replace traditional incandescent signals of similar luminous output. However, one aspect of LED technology that is not satisfactorily resolved is the application of LEDs under high temperature conditions. Such high temperature conditions may be originated from internal LED energy consumption and/or external environment temperature. LED lamps exhibit serious light output sensitivity to chip temperature. High temperature can cause an LED device to have lower lumen output, lower reliability, or even be permanently degraded. The well known Arrhenius function approximately models this behavior, and predicts elevated temperature lifetimes of less than one year at temperatures approaching 100° C.

Liquid cooling technologies have been attempted to solve the heat dissipation problem in electronic equipments. For example, U.S. Pat. No. 5,380,956 discloses a multi-chip cooling method for computers and servers. Chips are mounted on a plurality of substrates in such a manner that portions of the top and bottom surfaces of the chips are exposed. The substrates are arranged inside a module so that when coolant flows through the module, the coolant is in contact with the exposed portions of the top and bottom surfaces of the chips, thereby extracting heat from the chips.

U.S. Pat. No. 4,879,629 describes a method for concurrently cooling a plurality of integrated circuit chips mounted on a substrate. This is achieved by passing coolant through channels formed between the elongated fins of a plurality of heat sinks. The plurality of heat sinks are attached to a plurality of heat-conducting studs that are attached to the plurality of integrated circuit chips for receiving heat generated by the integrated circuit chips.

U.S. Pat. No. 5,978,220 teaches that chips are mounted on a substrate and the substrate is coupled to a cold plate. The cold plate is kept cool by flowing coolant thereonto, thereby indirectly cooling the chips.

U.S. Pat. No. 5,901,037 discloses that elongated micro channels are formed in a substrate that carries one or more transistor dies. Coolant is fed through the micro channels for extracting the heat from the dies.

A number of cooling methodologies have also been described by Bar-Cohen (Bar-Cohen, A., “Thermal Management of Electronic Components with Dielectric Liquids”, JSME International Journal, Series B, vol. 36, No 1, 1993), by Simons (Simons, R. E., “Bibliography of Heat Transfer in Electronic Equipment”, 1989, IBM Corporation), by Incropera (Incropera, F. P., “Convection Heat Transfer in Electronic Equipment Cooling”, Journal of Heat Transfer, November 1988, Vol. 110/1097), by Bergles (Bergles, A. E., “Liquid Cooling for Electronic Equipment”, International Symposium on Cooling Technology for Electronic Equipment, March 1987), by Chu and Chrysler (Chu, R. C., and Chrysler, G. M., “Electronic Module Coolability Analysis”, EEP-Vol. 19-2, Advances in Electronic Packaging-1997 Volume 2, ASME 1997), and by Nakayama (Nakayama, W., “Liquid-Cooling of Electronic Equipment: Where Does It Offer Viable Solutions?”, EEP-Vol. 19-2, Advances in Electronic Packaging-1997 Volume 2, ASME 1997).

However, current LED designs completely rely on the heat removal from back side of the package. No heat transfer from frontal side of the LED packages except for very weak natural convection which is about 1-2% of the overall heat.

Advantageously, the present invention provides an optoelectronic device comprising a heat source and a heat transfer fluid. The device has gained many desirable properties such as improved heat removing efficiency, lower chip/junction temperature, increased lumen output, longer operational lifetime, and better reliability, among others.

### BRIEF DESCRIPTION OF THE INVENTION

One aspect of the present exemplary embodiment is to provide an optoelectronic device comprising a radiation source and a heat transfer fluid.

Another aspect of the present exemplary embodiment is to provide a method of preparing an optoelectronic device, which comprises (i) providing a semiconductor heat source, and (ii) filling a space in the vicinity of the semiconductor heat source with a heat transfer liquid with desired optical characteristics.

### BRIEF DESCRIPTION OF THE DRAWINGS

FIG. 1 shows the refractive index of a typical optical heat transfer liquid along the wavelength range of 400 nm-1600 nm, as measured with a prism coupler, in an embodiment of the present invention;

FIG. 2 shows the optical absorption spectrum of a heat transfer liquid, as measured with a spectrophotometer, in an embodiment of the present invention;

FIG. 3 illustrates an optoelectronic device such as a LED assembly with top-side passive cooling via transparent, inert and dielectric fluid, in an embodiment of the present invention;

FIG. 4 illustrates an optoelectronic device such as a LED assembly with top-side passive cooling via transparent, inert and dielectric fluid; and back-side passive cooling via inert and dielectric fluid, in an embodiment of the present invention;

FIG. 5 illustrates an optoelectronic device such as a LED assembly with top-side passive cooling via transparent, inert and dielectric fluid; back-side passive cooling via inert and dielectric fluid; and a heat sink with fins, in an embodiment of the present invention;

FIG. 6 illustrates an optoelectronic device such as a LED assembly with top-side passive cooling via transparent, inert and dielectric fluid; and back-side active cooling via inert and dielectric fluid using a synthetic jet actuator, in an embodiment of the present invention; and

FIG. 7 illustrates an optoelectronic device such as a LED assembly with top-side passive cooling via transparent, inert and dielectric fluid; and back-side active cooling via inert and dielectric fluid, which is circulated to a heat exchanger located outside the back-side fluid, in an embodiment of the present invention.

### DETAILED DESCRIPTION OF THE INVENTION

The present invention discloses liquid cooling from photonics devices in general, but particularly for LEDs and lasers. Two novel ideas cooling from backside of the board via liquid cooling, or topside cooling—means over the chip—via liquid cooling, or a combination of both is intended.

It is to be understood herein, that if a “range” or “group” is mentioned with respect to a particular characteristic of the present disclosure, for example, percentage, chemical species, and temperature etc., it relates to and explicitly incorporates herein each and every specific member and combination of sub-ranges or sub-groups therein whatsoever. Thus, any specified range or group is to be understood as a shorthand way of referring to each and every member of a range or group individually as well as each and every possible sub-range or sub-group encompassed therein; and similarly with respect to any sub-ranges or sub-groups therein.

Optoelectronic device of the invention may be any solid-state and other electronic device for generating, modulating, transmitting, and sensing electromagnetic heat in the ultraviolet, visible, and infrared portions of the spectrum. Optoelectronic devices, sometimes referred to as semiconductor devices or solid state devices, include, but are not limited to, LED packages, charge coupled-LED devices (CCDs), photodiodes, vertical cavity surface emitting lasers (VCSELs), phototransistors, photocouplers, opto-electronic couplers, and the like.

The heat source of the invention may be, for example, a light emitting diode (LED), a lamp, a laser, or any other source of heat.

In embodiments, the heat source comprises an LED chip that contains a p-n junction of any semiconductor layers capable of emitting the desired heat. For example, the LED chip may contain any desired Group III-V compound semiconductor layers, such as GaAs, GaAlAs, GaN, InGaN, GaP, etc., or Group II-VI compound semiconductor layers such as ZnSe, ZnSSe, CdTe, etc., or Group IV-IV semiconductor layers, such as SiC. The LED chip may also contain other layers, such as cladding layers, waveguide layers and contact layers. Any suitable phosphor material may be used with the LED chip. For example, a yellow emitting cerium doped yttrium aluminum garnet phosphor (YAG:Ce³⁺) may be used with a blue emitting InGaN active layer LED chip to produce a visible yellow and blue light output which appears white to a human observer. Other combinations of LED chips and phosphors may be used as desired. A detailed disclosure of a UV/blue LED-Phosphor Device with efficient conversion of UV/blue Light to visible light may be found in U.S. Pat. No. 5,813,752 (Singer) and U.S. Pat. No. 5,813,753 (Vriens).

The heat transfer fluid may be selected from any conventional heat transfer fluids such as optical fluid for photonics and optics; as well as recently developed nano fluids. Nano fluids are generally nano particles that are optically transparent and can enhance heat transfer significantly as well as alter the index of refraction of the fluid. Nano fluids are disclosed in, for example, U. S. Choi, Developments and Applications of Non-Newtonian Flows, edited by D. A. Siginer and H. P. Wang, The ASME, New York, 1995, Vol. 231/MD-Vol. 66, pp. 99-105; and Sarit Kumar Das, Nandy Putra, Peter Thiesen, and Wilfried Roetzel, “Temperature Dependence of Thermal Conductivity Enhancement for Nanofluids”, Journal of Heat Transfer, August 2003, Volume 125, Issue 4, pp. 567-574, the entire disclosures of which are incorporated herein by reference.) Typically, the nano fluid can enhance the heat transfer efficiency up to 40%, comparing to bare fluid such as plain cooling water.

In various exemplary embodiments, the heat transfer fluid exhibits suitable optical properties for using in optoelectronic applications such as LED manufacture. Preferably, the heat transfer fluid can be transparent and visible to UV-visible light. For example, the heat transfer fluid can have an optical absorption of less than about 2%/mm, preferably less than about 1%/mm, and more preferably less than about 0.5%/mm, at any wavelength in the range of from about 300 nm to about 800 nm. Alternatively, the heat transfer fluid can have an optical absorption of less than about 1.5 dB/cm, preferably less than about 0.8 dB/cm, and more preferably less than about 0.3 dB/cm, at any wavelength in the range of from about 300 nm to about 800 nm.

The refractive index of the heat transfer fluid matches well with that of the heat source such as chips, lens, and other components in an optoelectronic device. The refractive index of the heat transfer fluid can generally range from about 1.2 to about 2.8, preferably range from about 1.5 to about 2.7, and more preferably range from about 1.5 to about 2.2, as measured, for example, at any wavelength in the range of from about 300 nm to about 800 nm (25° C.) using the method of ASTM D-1218.

In preferred embodiments, the refractive index of the heat transfer fluid is stable over a wide range of working temperature of the optoelectronic device. For example, the refractive index of the heat transfer fluid vs. temperature can generally range from about 1.5 to about 1.58, preferably range from about 1.5 to about 1.55, and more preferably range from about 1.5 to about 1.51 such as −4×10⁻⁴/° C., as measured, for example, at any wavelength in the range of from about 300 nm to about 800 nm using the method of ASTM D-1218.

In various exemplary embodiments, the heat transfer fluid exhibits suitable electrical properties for using in optoelectronic applications such as LED manufacture. The heat transfer fluid is preferably dielectric, and is capable of absorbing heat without causing electrical short-circuit. For example, the volume resistivity (25° C.) of the heat transfer fluid can be generally at least 1M (Ωcm), preferably at least 100M (Ωcm), and more preferably at least 1000M (Dem) such as>10¹⁵ (Ωcm), as measured with the method of ASTM D-257. The dielectric strength (kV, 0.1″ gap) of the heat transfer fluid can be generally at least 1, preferably at least 10 (such as 38), and more preferably at least 100.

In various exemplary embodiments, the heat transfer fluid exhibits suitable thermo-mechanical properties for using in optoelectronic applications such as LED manufacture. For example, the thermal expansion by volume of the heat transfer fluid at 25° C. can generally range from about 0.0001 cc/cc/° C. to about 0.001 cc/cc/° C., preferably range from about 0.00001 cc/cc/° C. to about 0.0001 cc/cc/° C., and more preferably range from about 0.000001 cc/cc/° C. to about 0.00001 cc/cc/° C. such as 8×10⁻⁴ cc/cc/° C., as measured with the method of ASTM D-1903.

The flash and fire point, as determined by ASTM D-92, are critical properties for the heat transfer fluid. The flash point represents the temperature of the fluid that will result in an ignition of a fluid's vapors when exposed to air and an ignition source. The fire point represents that temperature of the fluid at which sustained combustion occurs when exposed to air and an ignition source. The flash point of the heat transfer fluid can be generally at least 175° C., preferably at least 200° C., and more preferably at least 300° C. The fire point of the heat transfer fluid can be generally at least 225° C., preferably at least 250° C., and more preferably at least 350° C.

Because the heat transfer fluid typically cools the optoelectronic device by convection, the viscosity of the heat transfer fluid at various temperatures is another important factor in determining its effectiveness. Viscosity is a measure of the resistance of a fluid to flow. The flow-ability of a fluid is typically discussed in terms of its kinematic viscosity, which is measured in stokes and is often referred to merely as “viscosity”. The kinematic viscosity measured in stokes is equal to the viscosity in poises divided by the density of the fluid in grams per cubic centimeter, both measured at the same temperature. The viscosity of the heat transfer fluid at 25° C. can generally range from about 0.1 cP to about 2000 cP, preferably range from about 0.3 cP to about 500 cP, and more preferably range from about 0.5 cP to about 100 cP, even up to 1000 cP, as measured with the method of ASTM D-1084.

In various exemplary embodiments, the heat transfer fluid exhibits suitable chemical and physical properties for using in optoelectronic applications such as LED manufacture. The heat transfer fluid is preferably chemically inert, environmentally friendly, non-volatile, non-flammable, non-toxic, and compatible with materials used in an optoelectronic device. For example, the heat transfer fluid exhibits zero or minimal Ozone Depletion Potential (ODP). The boiling point of the heat transfer fluid can generally range from about 50° C. to about 400° C., preferably range from about 50° C. to about 300° C., and more preferably range from about 50° C. to about 200° C.

In a variety of exemplary embodiments, the heat transfer fluid can be selected from the group consisting of perfluorocarbon (PFC), polychlorinated biphenyl (PCB), dimethyl silicone, hydrocarbon oil, mineral oil, paraffinic oil, naphthenic oil, aromatic hydrocarbon, polyalphaolefin, polyol ester, vegetable oil, and the like, and the mixture thereof.

Perfluorocarbons are fully-fluorinated compounds, and can be synthesized using known method or obtained from commercial sources. For example, 3M™ Fluorinert™ electronic liquids can be used as the heat transfer fluid in the present invention. In preferred embodiments, Fluorinert liquid FC-72 can be used as the heat transfer fluid. Fluorinert liquid FC-72 has high dielectric constant, and thus will not damage electronic equipment in the event of a leak or other failure. FC-72 liquid is also chemically stable, compatible with sensitive materials, nonflammable and practically non-toxic.

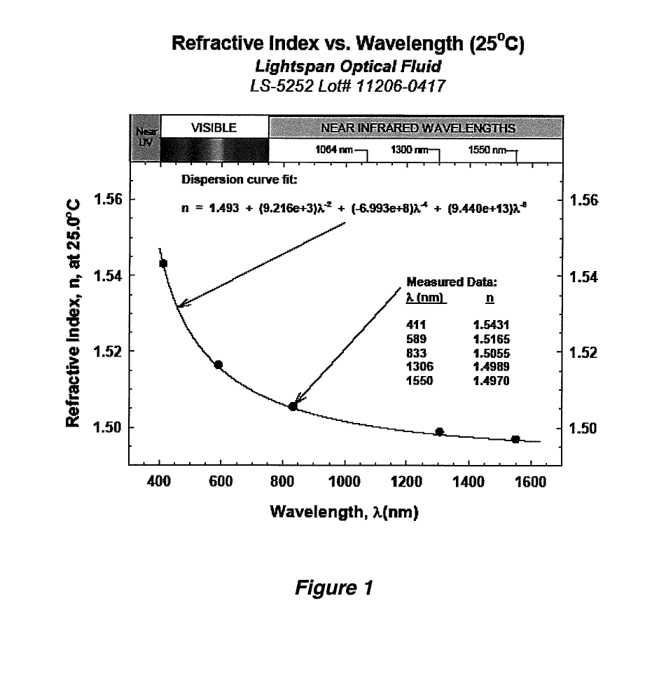

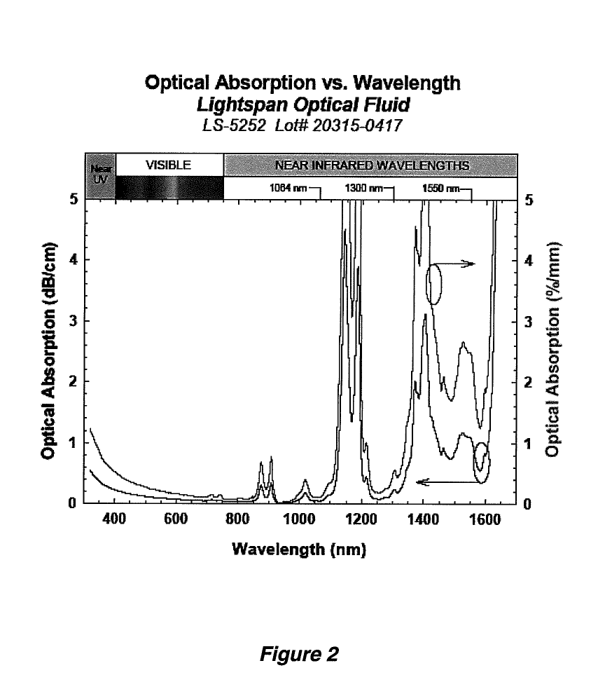

As another example, Lightspan™ LS-5252 can also be used as the heat transfer fluid in the present invention. LS-5252 is manufactured by Lightspan LLC, 14 Kendrick Road, Wareham, Mass. 02571. The liquid exhibits many desirable properties for application in an optoelectronic system. For example, with a refractive index of 1.52, it matches many optoelectronic components such as optical plastics, glasses and semiconductors etc. FIG. 1 shows the refractive index along the wavelength range of 400 nm-1600 nm, as measured with a prism coupler. LS-5252 is optically clear, allowing efficient optical transmission for wavelengths>350 nm. FIG. 2 shows the optical absorption spectrum of LS-5252, as measured with a spectrophotometer.

LS-5252 is also chemically inert, non-toxic, and compatible with optical grade materials. With low volatility, the liquid can eliminate recondensation contamination and ensure long service life. LS-5252 contains low level of ionics, and will not degrade sensitive semiconductors and metals.

Examples of aromatic hydrocarbon include triaryl methanes, triaryl ethanes, diaryl methanes such as:

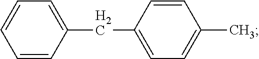 [SMILES: Cc1ccc(Cc2ccccc2)cc1]

diaryl ethanes such as:

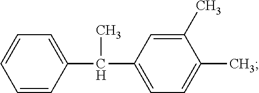 [SMILES: Cc1ccc(C(C)c2ccccc2)cc1C]

alkylated biphenyls such as:

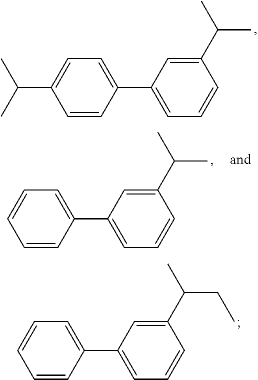

monoaromatics with larger alkyl groups such as:

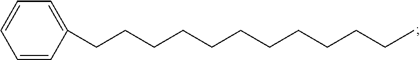 [SMILES: CCCCCCCCCCCCc1ccccc1]

naphthalenes such as:

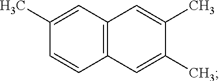

and the like, and the mixture thereof.

Polyalphaolefins (PAO's) are derived from the polymerization of olefins where the unsaturation is located at the 1, or alpha, position. The preferred products are based upon hexene (C₆), octene (C₈), decene (C₁₀) or dodecene (C₁₂).

Polyol esters result from the chemical combination of polyalcohol compounds with organic acids containing a variety of alkyl groups. The chain length of the alkyl group on the polyol ester is typically between C₅ and C₂₀. Examples of suitable polyol esters are represented by the following formulas:

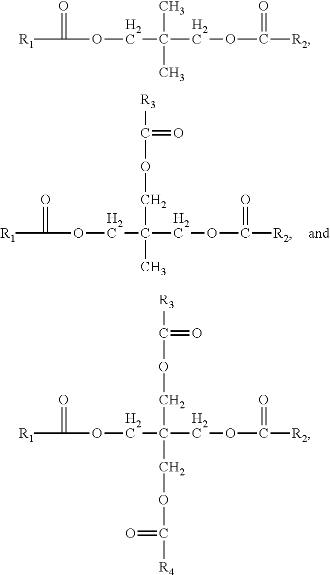

in which R₁, R₂, R₃, and R₄ are independently of each other selected from C₅ to C₂₀ alkyl groups.

Vegetables oils are natural products derived from plants, and most commonly from plant seeds. The oils are a source of a general class of compounds known as triglycerides, which derive from the chemical combination of glycerin with naturally occurring mono carboxylic acids, commonly referred to as fatty acids. Fatty acids are classified by the number of carbons contained in the alkyl chain and by the number of carbon double bonds incorporated into the carbon chain of the fatty acid. For example, the reaction of three saturated, mono- or poly-unsaturated fatty acids having carbon chain lengths of from four carbons to twenty-two carbons with glycerin forms a triglyceride molecule with the general formula:

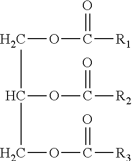

in which R₁, R₂, and R₃ are independently of each other selected from C₄ to C₂₂ hydrocarbon chains with 0 to 3 unsaturation levels.

In exemplary embodiments, the optoelectronic device of the invention is a LED based lighting device, in which the LED can be placed on the board in a variety of ways such as direct attach or chip on board.

The present invention provides a method of preparing an optoelectronic device, which comprises (i) providing a heat source, and (ii) filling a space in the vicinity of the heat source with a heat transfer liquid.

Preferably, the heat transfer fluid is confined in or with the optoelectronic device of the invention. For example, the heat transfer fluid can be used to fill the individual LED cup or LED lighting fixture. In preferred embodiments, all four sides as well as top and bottom of the device are used to dissipate heat, and the efficiency of the overall heat removal is thus improved.

In a first exemplary embodiment, the heat transfer fluid fills at least part of the gap between a chip and a lens. In such embodiment, epoxy filler may be optionally reduced or even eliminated, except for the applications where there is a structural need.

In a second exemplary embodiment, the heat transfer fluid fills at least part of the gap between a lens and the housing, typically external housing.

For some specific applications, the first exemplary embodiment and the second exemplary embodiment can be combined. Both parts are in communication via micron size holes made on the LED PCB or around the PCB between enclosure and LED board.

In an optoelectronic device, conventional solid and/or air cooling may be optionally used in combination with the liquid cooling of the invention. For example, any means of ventilation can be optionally used to cool an optoelectronic device, such as vents, louvers, fans and the like. A LED device can incorporate a metallic contact pad into the back of the LED package to transfer the heat out through the back of the LED. In practice, it is desirable that this contact pad in the LED package be placed into contact with further heat dissipation surfaces to effectively cool the LED package. A heat sink can also be used to lower the temperature of LED array. In an LED lamp assembly, a heat absorber in the form of an electrically insulating sheet can be disposed between the circuit board holding the LEDs and the heat sink.

Thermally conductive substrates can also be used in an optoelectronic device such as LED. These substrates generally perform a mechanical component support function, also provide for electrical interconnection to and between components, and optimally allow for the extraction and dissipation of component generated heat. Some of the more successful approaches include ceramic, non conductive cermet or coated metallic substrates which are then laminated with copper, and are processed like conventional printed circuit boards. The most common insulated metal substrates employ an aluminum or copper base, and a thin polyamide or resinous insulating coating that bonds the copper laminate to the substrate material. The effective thermal conductance of the dielectric insulator is relatively high because it is very thin.

As a skilled artisan can appreciate, an optoelectronic device may comprise many parts that are made from a wide variety of organic or inorganic materials. For example, optoelectronic components may include semiconductor chip, lead frame, bond wire, solder, electrode, pad, contact layer, phosphor layer, and dielectric layer etc. These optoelectronic components may be made of or made from materials, for example, metals such as aluminum, gold, silver, tin-lead, nickel, copper, and iron, and their alloys; silicon; passivation coatings such as silicon dioxide and silicon nitride; aluminum nitride; alumina; fluorocarbon polymers such as polytetrafluoroethylene and polyvinylfluoride; polyamides such as Nylon; organic resins such as polyimide; polyesters; ceramics; plastic; and glass etc. Taking a LED chip as an illustrative example, it may contain any desired Group III-V compound semiconductor layers, such as GaAs, GaAlAs, GaN, InGaN, GaP etc., or Group II-VI compound semiconductor layers such as ZnSe, ZnSSe, CdTe, etc., or Group IV-IV semiconductor layers, such as SiC. The phosphor layer or coating, as another illustrative example, may be cerium-doped yittrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂ (“YAG:Gd,Ce”), (Y₁₋ₓCeₓ)₃(Al_{5-y}Ga_{y})O₁₂ (“YAG:Ga,Ce”), (Y_{1-x-y}GdₓCe_{y})(Al_{5-z}Ga_{z})O₁₂ (“YAG:Gd,Ga,Ce”), and (Gd₁₋ₓCeₓ)Sc₂Al₃O₁₂ (“GSAG”), where and Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. Non-limiting examples of phosphors that are efficiently excited by light of 300 nm to about 500 nm include green-emitting phosphors such as Ca₈Mg(SiO₄)₄Cl₂:Eu²⁺, Mn²⁺; GdBO₃:Ce³⁺, Tb³⁺; CeMgAl₁₁O₁₉:Tb³⁺; Y₂SiO₅:Ce³⁺, Tb³⁺; and BaMg₂Al₁₆O₂₇:Eu²⁺, Mn²⁺ etc.; red-emitting phosphors such as Y₂O₃:Bi³⁺,Eu³⁺; Sr₂P₂O₇:Eu²⁺,Mn²⁺; SrMgP₂O₇:Eu²⁺,Mn²⁺; (Y,Gd)(V,B)O₄:Eu³⁺; and 3.5MgO.0.5MgF₂.GeO₂:Mn⁴⁺ (magnesium fluorogermanate) etc.; blue-emitting phosphors such as BaMg₂Al₁₆O₂₇:Eu²⁺; Sr₅(PO₄)₁₀Cl₂:Eu²⁺; (Ba,Ca,Sr)(PO₄)₁₀(Cl,F)₂:Eu²⁺; and (Ca,Ba,Sr)(Al,Ga)₂S₄:Eu²⁺ etc.; and yellow-emitting phosphors such as (Ba,Ca,Sr)(PO₄)₁₀(Cl,F)₂:Eu²⁺,Mn²⁺ etc.

When the heat transfer fluid is utilized for the thermal management of an optoelectronic device, heat can be easily transferred to housing boundaries. For example, the enclosure on top of a LED can be filled with the fluid to take the advantage of effective bulb/frontal surface area. Without being bound to any particular theories, it is believed that heat is transferred with either natural convection buoyancy or boiling heat transfer. The optoelectronic device of the invention has gained many desirable properties such as improved heat removing efficiency, lower chip/junction temperature, increased lumen output, longer operational lifetime, and better reliability, among others. For example, given all other same conditions, the heat removing efficiency of the optoelectronic device according to the invention can increase at least about 10%, preferably at least 50%, and more preferably at least 100%, as compared to a same optoelectronic device without the heat transfer fluid. The heat removing efficiency may be determined using ASTM D 5470, thermal impedance measurement.

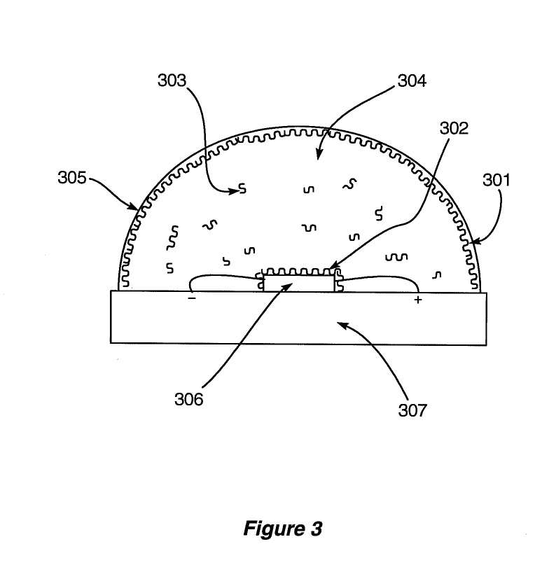

With reference to FIG. 3, an LED chip 306 is surrounded by a frontal lens 305 and is mounted on a board 307. An LED array made up of a plurality of LEDs can be used too. The LEDs can be conventional LEDs that are known in the art. The LED chip 306 receives electrical power from a power source (not shown). The mounting of the LED and the electrical connections used to supply power to the LED are known in the art, and therefore need no further description. The space defined between the lens 305 and the board 307 is filled with heat transfer fluid 304 such as transparent, inert and dielectric fluid, for example mineral oil, lightspan 5262, and cargille 5610. At least part of the internal surface of the lens 305 is covered with phosphor coating 301. At least part of the surface of the chip 306 can also be covered with phosphor coating 302. Phosphor particles 303 with e.g. a size of from 1 nm to 100,000 nm are dispersed in the heat transfer fluid 304.

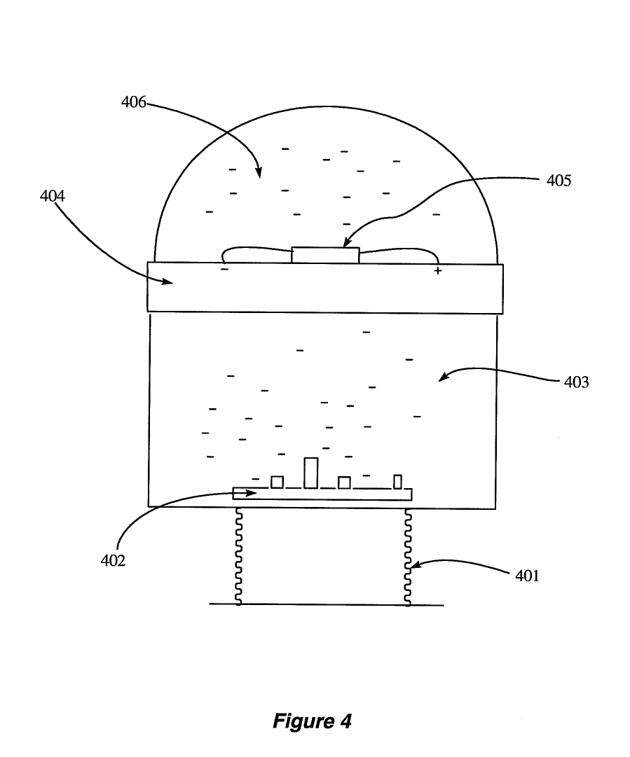

A LED chip can be cooled by two or more bodies of heat transfer fluid. With reference to FIG. 4, an LED chip 405 is surrounded by a frontal lens and is mounted on a board 404. The LEDs arrangement and power supply etc. according to this figure are similar to that of FIG. 3. The space defined between the frontal lens and the board 404 is filled with the first body of heat transfer fluid 406 such as transparent, inert and dielectric fluid as described above. The backside of the LED board assembly is enclosed to form a space 403, which is filled with the second body of heat transfer fluid such as inert and dielectric fluid as described above. The second body of heat transfer fluid does not have to be transparent. The heat transfer fluid provides passive convective cooling and free convection. The power electronics 402 is used with an Edison/screw base 401. Optionally, one or more communication holes (not shown) can be used at the board, with same or different and optically transparent heat transfer fluid(s).

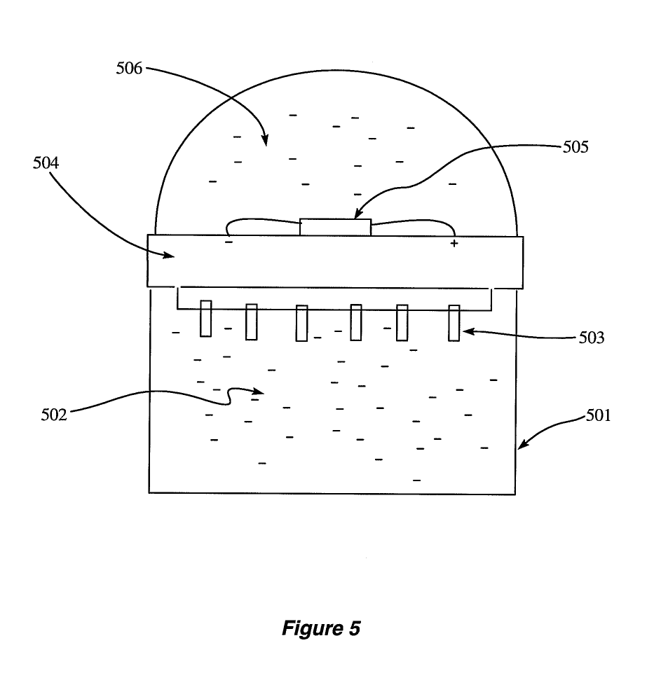

With reference to FIG. 5, an LED chip 505 is surrounded by a frontal lens and is mounted on a board 504. The LEDs arrangement and power supply etc. according to this figure are similar to that of FIG. 3. The space defined between the frontal lens and the board 504 is filled with the first body of heat transfer fluid 506 such as transparent, inert and dielectric fluid, as described above. The backside of the LED board assembly is enclosed to form a space 501, which is filled with the second body of heat transfer fluid 502. The heat transfer fluid provides passive convective cooling and free convection. Within the space 501, a heat sink with fins 503 is connected to the back side of the board 504. Optionally, one or more communication holes (not shown) can be used at the board, with same or different and optically transparent heat transfer fluid(s).

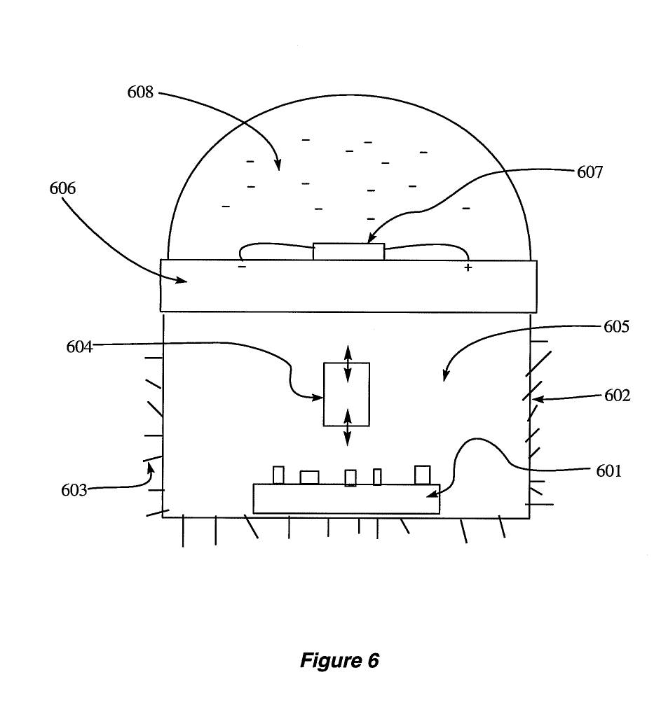

A synthetic jet can provide additional cooling at the backside of the LED board by means of impingement or atomizing fluid over the LED board. With reference to FIG. 6, an LED chip 607 is surrounded by a frontal lens and is mounted on a board 606. The LEDs arrangement and power supply etc. according to this figure are similar to that of FIG. 3. The space defined between the frontal lens and the board 606 is filled with the first body of heat transfer fluid 608 such as transparent, inert and dielectric fluid, as described above. The backside of the LED board assembly is enclosed to form a space 605, which is filled with the second body of heat transfer fluid. Heat sink 602 with or without fins 603 is used with the space 605. Disposed within the space 605 include power electronics 601 and a synthetic jet actuator 604. The synthetic jet cooling device 604 functions as a fluid current generator for heat dissipating. In an embodiment, the device 604 includes a chamber and a diaphragm. As the diaphragm moves into the chamber, decreasing the chamber volume, fluid is ejected from the chamber through the orifice. As the fluid passes through the orifice, the flow separates at the sharp edges of the orifice and creates vortex sheets which roll up into vortices. These vortices move away from the edges of the orifice under their own self-induced velocity. As the diaphragm moves out of the chamber, increasing the chamber volume, ambient fluid is drawn into the orifice, and thus into the chamber. Since the vortices are already removed from the edges of the orifice, they are not affected by the ambient fluid being entrained into the chamber. As the vortices travel away from the orifice, they synthesize a jet of fluid, a “synthetic jet”, through entrainment of the ambient fluid.

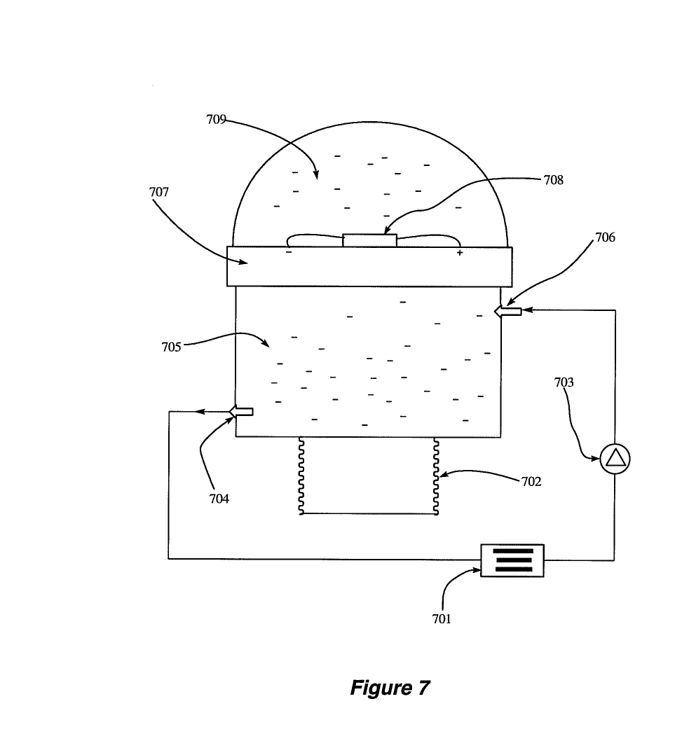

Heat transfer liquid can be connected to an external heat exchanger and removes heat to ambient environment. A pump can be added to the system to circulate the fluid. Alternatively, a passive thermo-syphon system provides fluid recirculation. Referring to FIG. 7, an LED chip 708 is surrounded by a frontal lens and is mounted on a board 707. The LEDs arrangement and power supply etc. according to this figure are similar to that of FIG. 3. The space defined between the frontal lens and the board 707 is filled with a first body of heat transfer fluid 709 such as transparent, inert and dielectric fluid, as described above. The backside of the LED board assembly is enclosed to form a space 705, which is filled with a second body of heat transfer fluid. The assembly includes an Edison/screw base 702. There are an inlet orifice 706 and outlet orifice 704 in the enclosed space 705 for circulation of second body of heat transfer fluid via a conduit. When the heat transfer fluid is circulated in the conduit, it goes though a heat exchanger 701 to dissipate heat to environment. Optionally, the fluid circulation is driven by a pump 703 to improve cooling efficiency. Optionally, one or more communication holes (not shown) can be used at the board, with same or different and optically transparent heat transfer fluid(s) between frontal and backside of the LED board.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All patents and publications cited herein are incorporated herein by reference.

1. A lamp comprising a heat source selected from a light generating light emitting diode (LED) or laser and a light transmissive housing, and wherein a heat transfer fluid at least substantially fills a space between said light transmissive housing and the heat source.

2. The lamp according to claim 1, in which the heat transfer fluid is dielectric and does not cause any shorts in the optoelectronic device, wherein the fluid preferably has an optical absorption of less than about 2%/mm at any wavelength in the range of from about 300 nm to about 800 nm; the heat transfer fluid is a dielectric fluid with a volume resistivity (25° C.) of at least 1M (Ωcm), as measured with the method of ASTM D-257; the refractive index of the heat transfer fluid ranges from about 1.2 to about 2.5 at any wavelength in the range of from about 400 nm to about 800 nm; and the thermal expansion by volume of the heat transfer fluid at 25° C. ranges from about 0.000001 cc/cc/° C. to about 0.001 cc/cc/° C., as measured with the method of ASTM D-1903.

3. The lamp according to claim 1, in which the heat transfer fluid is selected from the group consisting of perfluorocarbon (PFC), polychlorinated biphenyl (PCB), dimethyl silicone, hydrocarbon oil, mineral oil, paraffinic oil, naphthenic oil, aromatic hydrocarbon, polyalphaolefin, polyol ester, vegetable oil, nano-fluids, and the mixture thereof.

4. The lamp according to claim 1, in which the heat transfer fluid comprises Fluorinert liquid FC-72, Novec fluid such as HFE 7100, Lightspan™ LS-5252, or any combination thereof.

5. The lamp according to claim 3, in which the aromatic hydrocarbon comprises triaryl methanes, triaryl ethanes, diaryl methanes, diaryl ethanes, alkylated biphenyls, monoaromatics with large alkyl groups, naphthalenes, and the mixture thereof.

6. The lamp according to claim 3, in which the polyalphaolefins are derived from the polymerization of hexene (C₆), octene (C₈), decene (C₁₀) or dodecene (C₁₂).

7. The lamp according to claim 3, in which the vegetable oil comprises a triglyceride molecule with the general formula: 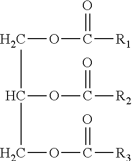
wherein R₁, R₂, and R₃ are independently of each other selected from C₄ to C₂₂ hydrocarbon chains with 0 to 3 unsaturation levels.

8. The lamp according to claim 1, in which the heat transfer fluid further comprises dispersed phosphor particles with a size of from 1 nm to 5000 nm.

9. (canceled)

10. The lamp according to claim 9, in which the LED contains a Group III-V compound semiconductor layer such as GaAs, GaAlAs, GaN, InGaN, or GaP; a Group II-VI compound semiconductor layer such as ZnSe, ZnSSe, or CdTe; or a Group IV-IV semiconductor layer such as SiC.

11. The lamp according to claim 1, further comprising a solid cooling means and/or an air cooling means.

12. (canceled)

13. The lamp according to claim 1, which is a LED package and the heat transfer liquid, locates in the vicinity of bulb/frontal surface area.

14. (canceled)

15. (canceled)

16. (canceled)

17. The lamp according to claim 1, which comprises a first body of heat transfer fluid located in the top-side of the heat source; and a second body of heat transfer fluid located in the back-side of the heat source.

18. The lamp according to claim 17, in which a synthetic jet actuator is operated with the second body of heat transfer fluid.

19. The lamp according to claim 17, in which the second body of heat transfer fluid is circulated to a heat exchanger located outside the body of fluid.

20. The lamp according to claim 1, which has a heat removing efficiency at least about 10% higher than that of the same optoelectronic device but without the heat transfer fluid.

21. A method of preparing a lamp, which comprises (i) providing an LED or laser light and heat source, and (ii) filling a space in the vicinity of the heat source with a heat transfer liquid which is hermetically sealed.

22. (canceled)

23. (canceled)

24. The lamp of claim 17, wherein said heat source is disposed on a front surface of a printed circuit board (PCB) and said first body of heat transfer fluid is in direct contact with the heat source and said second body of heat transfer fluid is in direct contact with a back surface of the PCB.

25. The lamp of claim 1, wherein said fluid comprises an oil.

26. The lamp of claim 1, further comprising a phosphor in association with the light transmissive housing.

27. The lamp of claim 1, wherein a flash point of the fluid is at least 175° C.
